(19) United States
(12) Patent Application Publication
(10) Pub. No.: US 2019/0085454 A1
(43) Pub. Date: Mar. 21, 2019

(54) VERTICAL DEPOSITION SYSTEM

(71) Applicant: STRUCTURED MATERIALS INDUSTRIES, INC., PISCATAWAY, NJ (US)

(72) Inventors: GARY S. TOMPA, BELLE MEADE, NJ (US); AARON FELDMAN, EDISON, NJ (US); NICK SBROCKEY, GAITHERSBURG, MD (US); SERDAL OKUR, PISCATAWAY, NJ (US); TOM SALAGAJ, WALLINGFORD, CT (US)

(21) Appl. No.: 16/133,865

(22) Filed: Sep. 18, 2018

Related U.S. Application Data
(60) Provisional application No. 62/606,329, filed on Sep. 19, 2017.

(51) Int. Cl. C23C 16/455; C23C 16/52; C23C 16/40; C23C 16/44; H01L 21/02

(52) U.S. Cl. CPC C23C 16/45565; C23C 16/52; H01L 21/02603; C23C 16/4417; C23C 16/45591; C23C 16/407

(57) ABSTRACT

A deposition system includes a process tube aligned vertically with a substrate holder therein positioned horizontally and perpendicular to a vertical tube axis. Through a bottom or top flange a first gas line connector is for injecting a first gas and a reactant gas connector is for injecting at a reactant gas. A feed line is coupled between the reactant gas connector and a reactant gas distributor having apertures for flowing the reactant gas towards a substrate. A vapor generating showerhead includes a gas distribution plate having flow distributing apertures on a precursor boat having gas inlets fluidically coupled to precursor holder trenches that hold a vapor generating material. The gas inlets have a flow path for flowing the first gas over the vapor generating material for generating a reactant vapor that flows out of the flow distributing aperture toward the substrate.

### CROSS REFERENCE TO RELATED APPLICATIONS

This application claims the benefit of Provisional Application Ser. No. 62/606,329 entitled “Vertical nanowire growth tool for uniform deposition of nanowires on large area substrates” filed Sep. 19, 2017, which is herein incorporated by reference in its entirety.

### STATEMENT OF GOVERNMENT SUPPORT

This invention with Government support under contract number NNX15CG10C awarded by the National Aeronautics and Space Administration (NASA). The U.S. Government has certain rights in the invention.

### FIELD

Disclosed embodiments relate to thin film and nanowires deposition systems.

### BACKGROUND

Having extraordinary physical, electrical, optical, and mechanical properties, nano-engineered materials, such as: nanoparticles, nanotubes (NTs), quantum dots (QDs), nanowires (NWs), nanofibers, and nanocomposites, have the potential to advance well-established products, and to create new products with new characteristics in many electrical, mechanical, optical, and biomedical applications, among others. Nanostructures can provide enhanced performances compared to bulk materials when they are used in similar applications. This is primarily due to the reduced dimensionality creating quantum confinement effects in the nanostructures which has a significant effect on their electrical, mechanical, and optical properties. Moreover, the high surface to volume ratio makes the nanostructures special for use in many different applications to save material and effort, among other features.

ZnO NWs are functional nanomaterials possessing novel properties due to their size and surface effects. As the dimension of ZnO shrinks down to nanometer scale, certain properties are enhanced due to aforementioned quantum-size-effect. Single-crystal ZnO NWs have superior electrical, optical and mechanical properties than their 2D and 3D counterparts due to a reduction in the defect density. It has been reported that the electron mobility of a single crystal ZnO NW can be nearly ten times larger than that of ZnO thin film transistors. Amongst the wide bandgap semiconductors, ZnO NWs can be deposited at temperatures typically between 400 and 900° C. The lower deposition temperatures allow significant latitude to integrate ZnO NWs with other materials and substrates. It can be alloyed with larger energy bandgap (Eg) oxide materials, such as MgO (Eg=7.8 eV), to engineer its bandgap or lower bandgap materials. ZnO can be doped with n-type dopants including Al, Ga, and In, to tune the conductivity without adversely affecting crystal quality.

In addition to Mg, other alloying materials can be used (e.g., Cd, Te, Se, S). Excellent photo-detection results have been observed from ZnO NWs, including large light induced conductivity increases and fast photo-detection response times. In addition to the ZnO based NW growth, conventional NW deposition systems can also be used to deposit a variety of other materials in the form of films and nanowires. Practical fabrication of NW-based devices still remains a challenge for several reasons, including large area uniform growth and elimination of depletion effects. The most common growth method for ZnO NWs is the vapor transport process. In this process, powders are vaporized at elevated temperatures and condensed onto a substrate to form the NWs. Temperature, pressure, and flow rates of carrying and reacting gases are important parameters to control the thermal vaporization and condensation during the NW growth. The relative position of the source materials and the substrate is also an important parameter that affects the NW growth process. The source powders are generally placed downstream away from the carrier gas and transported by the carrier gas during NW growth.

There are two main known vapor transport processes for NW growth: (i) catalyst free vapor-solid (VS) process and (ii) catalyst assisted vapor-liquid-solid (VLS) process. In the VLS technique, the growth takes place in the catalyst droplet interface. The catalyst are usually metals such as Au, Cu, Co, and Sn and for NW growth. The liquid catalyst absorbs the reactants since its sticking coefficient is much larger than the solid surface. The NW growth starts forming from the substrate-catalyst (solid-liquid) interface when the catalyst is supersaturated, and continues as long as the catalyst remains in the liquid state. The diameter of each NW is determined by the size of catalyst droplets as NWs are capped with catalyst particles and growth process parameters. Smaller catalysts provide thinner NWs. The metal catalyst can also be provided as part of the material transport process, such as by adding a metal precursor material to the growth vapor process stream.

NWs are conventionally grown in deposition systems comprising a horizontal tube furnace, with provisions for multiple zone heating along the tube. The source materials usually in the form of solid powders are placed in ceramic containers inside the tube. Due to the constraints of gravity, the ceramic containers are positioned horizontally on the lower side of the tube circumference. This configuration does not provide uniform flow of vapor from the source material, as considered across the tube diameter, in terms of vapor flow rate or vapor composition when multiple source materials are involved, especially if the differing materials are optionally evaporated at different temperatures.

The substrate sometimes comprising a plurality of wafers in a boat for receiving the NW deposition is also placed in the tube, at a specific distance downstream from the source(s). Due to gravity, the substrate is usually placed horizontally, in a direction parallel to the vapor flow direction. The relative positions of the source materials and the substrate are important parameters in NW growth. In these known NW growth systems, the process parameters are adjusted by moving the source material containers and the substrate horizontally along the tube axis which results in a narrow position range suitable for NW and thin film growth, typically a position range that is less than the wafer's diameter.

### SUMMARY

This Summary is provided to introduce a brief selection of disclosed concepts in a simplified form that are further described below in the Detailed Description including the drawings provided. This Summary is not intended to limit the claimed subject matter's scope.

This Disclosure recognizes conventional NW deposition systems have difficulty in producing uniform deposits of NW's and thin films on substrates (e.g., wafers) of generally any size. Large area substrates (such as at least 100 mm in diameter) exaggerate this deposition uniformity problem. The non-uniform deposition results from at least two effects. The vapor flux is non-uniform because the source materials are not uniformly positioned across the tube diameter. Also, since the substrate is positioned parallel to the vapor flow direction, the composition of the vapor flux is changing as deposition occurs down the length of the process tube due to differing rates of evaporated precursor depletion. Conventional NW and thin film growth systems also have poor control of the relative positions of the source materials and substrate, which is recognized herein to be an important parameter for NW and thin film growth. This is because of the finite size of the source material containers and the horizontal substrate distance variability to the source as measured along the tube's vertical axis direction. The relative position of the source materials and substrate will vary with position across the area of the substrate surface.

Disclosed aspects solve these problems that cause non-uniform NW and thin film depositions by providing a vertically configured deposition system (vertical deposition system) for depositing thin films and NWs on substrates. Disclosed vertical deposition systems include a gas distribution system comprising gas distribution plate on a precursor boat that holds a vapor generating material such as a sublimation material, which generates a reactant vapor flow that enables uniformly deposited thin films and doped or undoped NWs on large area substrates. Contrary to conventional deposition systems, the vertical orientation of disclosed vertical deposition systems provides several advantages. The reactant vapor flow from liquid or solid vapor generating material sources can be significantly uniform both in composition and molar flow rate in the horizontal direction (xy-plane) which is perpendicular to the vapor flow direction which is in the z-direction (or height) direction).

The substrate(s) being positioned in the horizontal plane and thus perpendicular to the reactant vapor flow from a disclosed vapor generating showerhead comprising a gas distribution plate on a precursor boat that flows out of flow distributing apertures of the gas distribution plate, where the reactant vapor from a source vapor generating material in the precursor boat is generally carried by a first gas (e.g., an inert gas such as argon) that provides a uniform reactant vapor flow. The uniform reactant vapor flow produces uniform deposits across the area of the substrate(s), including across the area of large area substrates (e.g., wafers), such as being 100 mm or more in diameter.

Uniform deposits provided by disclosed vertical deposition systems are not possible in conventional horizontal NW and thin deposition systems. In a conventional horizontal deposition system, liquid and solid source vapor generating materials cannot be positioned uniformly in a direction (xy plane) perpendicular to the vapor flow direction due to being constrained from the effect of gravity, where typically a gas flow is used to help push transport to the wafer(s) along, which generally results in thermal buoyancy/gravity induced non-uniform gas flows that causes non-uniform growth of NW and film materials.

A disclosed deposition system includes a process tube aligned vertically with a substrate holder therein positioned horizontally and perpendicular to a vertical tube axis. Through a bottom flange or a top flange a first gas line connector is provided for injecting a first gas that is inert or reacts slowly with reactant vapor to be generated that can comprise an inert gas (e.g., argon or helium), a reducing gas, or in some cases even an oxidizing gas, and there is a reactant gas line connector provided for injecting a reactant gas that can be an oxidizing gas.

A feed line is coupled between the reactant gas connector and a reactant gas distributor having apertures for flowing the reactant gas towards a substrate. A vapor generating showerhead includes a gas distribution plate having flow distributing apertures on a precursor boat that has a plurality of gas inlets fluidically coupled to precursor holder trenches that hold a vapor generating material. The gas inlets have a flow path for flowing the first gas over the vapor generating material for generating the reactant vapor that flows out of the flow distributing aperture toward the substrate for reacting with the reactant gas.

### BRIEF DESCRIPTION OF THE DRAWINGS

FIG. 1A is a cross sectional depiction of an example vertical deposition system including a disclosed vapor generating showerhead.

FIG. 1B is a cross sectional depiction of an example downward facing vertical deposition system that flips the vertical deposition system shown in FIG. 1A upside down (180 degrees).

FIG. 2A shows in more detail components within the vertical process tube with the gas distribution plate on the precursor boat shown in an exploded view.

FIG. 2B modifies FIG. 2A by adding spacer tubes above and below the gas distribution plate on the precursor boat so that the distance (shown as height) from the gas distribution plate on the precursor boat can be changed relative to the substrate holder.

FIG. 3A shows a top view of a gas distribution plate on a precursor boat.

FIG. 3B shows the precursor boat having a plurality of trenches shown as rings R1 to R8, where some of the rings are intended to hold vapor generating material.

FIG. 3C show an exploded view of a gas distribution plate and a precursor boat.

FIG. 3D shows a cross sectional view of a gas distribution plate on a precursor boat.

FIG. 3E shows an expanded view of the circled portion of the gas distribution plate on a precursor boat in FIG. 3D.

FIG. 4A depicts a first gas such as inert gas flowing through gas inlet flowing over powder shown within one of the rings shown as, then out an aperture in the gas distribution plate such as gas from ring R1 flows over the powder in ring R2, from ring R3 over R4, and so on.

FIG. 4B shows gas flowing out of the apertures of the reactive gas distribution ring. A feed line is shown that is coupled between the reactant gas connector and the gas distribution ring.

FIG. 4C shows an alternate operation mode for the precursor boat, where in addition to an inert or reactive gas flowing through an aperture and then over the powder and toward the substrate through an aperture in the precursor boat plate, there is a second or identical gas also flowed through a separate aperture in the precursor boat and through a separate aperture in the precursor boat plate.

FIG. 4D shows an alternate operation mode for the precursor boat, where in addition to an inert or reactive gas flowing through an aperture over the first powder Material I and out through aperture, an inert or reactive gas flows over a second powder Material II through a separate set of apertures in a separate ring in the precursor boat and then out through another aperture.

FIG. 5A shows a series of vapor generating in-line showerhead connections of the nature shown in FIGS. 3A to 3E and FIG. 4A, labeled as showerhead 1 and showerhead 2.

FIG. 5B shows a series of parallel vapor generating showerhead connections shown as showerhead 3 and showerhead 4.

FIG. 6 shows flow simulation results for temperature along the primary tube.

FIG. 7 shows flow simulation results for vapor concentration between the precursor boat and the substrate holder.

FIG. 8 is a schematic illustration of another example disclosed NW or thin film deposition system.

### DETAILED DESCRIPTION

This Disclosure includes a vertical deposition system that provides an improved growth process for producing NW or thin film materials on different substrates of interest. A method for production of nanowire materials based on chemical vapor deposition (CVD) and evaporation relying on the traits of VLS synthesis technique is also disclosed. The CVD apparatus and process can be used to produce NW and thin film based electronic/optoelectronic and related devices.

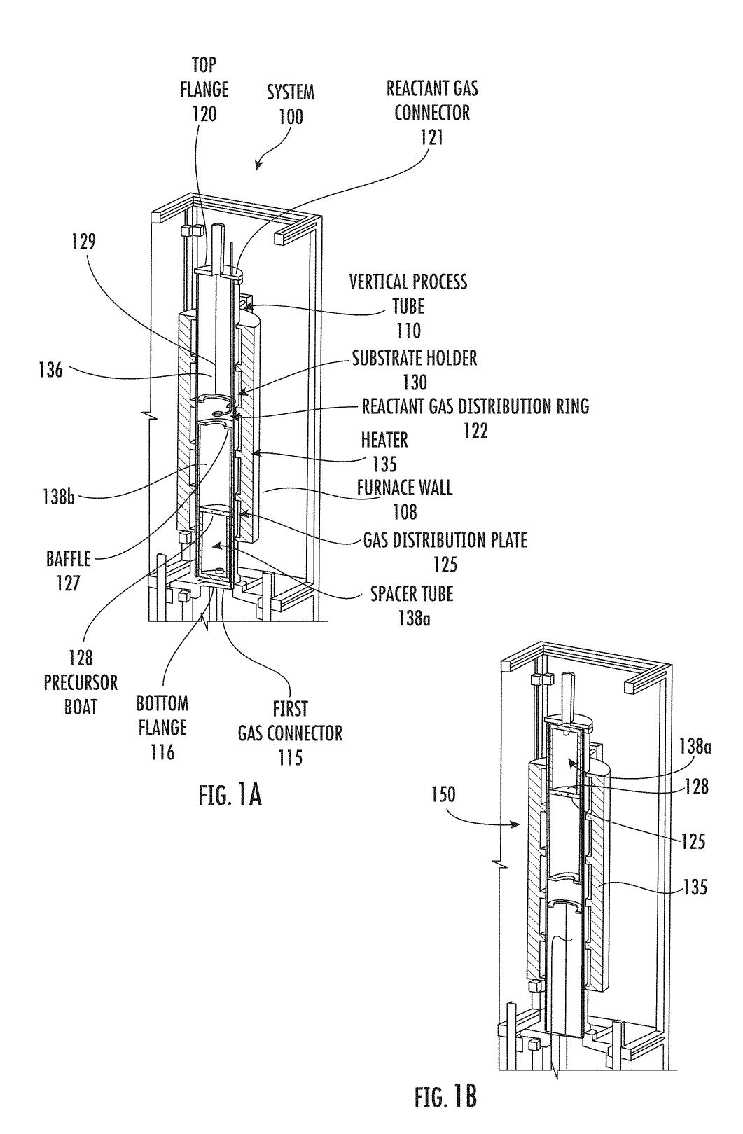

FIG. 1A is a cross sectional view of an example vertical deposition system 100 including a disclosed vapor generating showerhead 125/128 therein. The vertical deposition system 100 comprises a vertical process tube 110, such as generally comprising quartz, and is shown with a first gas connector 115 formed in a bottom flange 116, and a reactant gas connector 121 such as for injecting a reactant gas such as an oxygen or an oxygen containing gas (e.g., O₂, H₂O, NOₓ, O₃, etc.) within a top flange 120. Although an oxidizing gas as the first gas will react rapidly with some reactant vapor materials and thus need to be provided through a side of the vertical process tube 110 to avoid passing through the showerhead 125/128 before reaching the substrate holder 130, for other reactant vapor materials the reaction rate with oxidizing gas may be slow and depend on the temperature and the amount of time in contact. Accordingly, it may be possible in certain arrangements for the first gas to be a reactant gas that passes through the vapor generating showerhead 125/128 before reaching the substrate holder 130, such as for being brought in the process tube at temperature “A” because a reaction may not occur until later either at some higher temperature “B” (near the substrate holder 130) and/or only in the presence of some catalyst (e.g., on the wafer surface). A reactant gas distribution ring 122 receives reactant gas from the reactant gas connector 121. A heater is shown as heater 135.

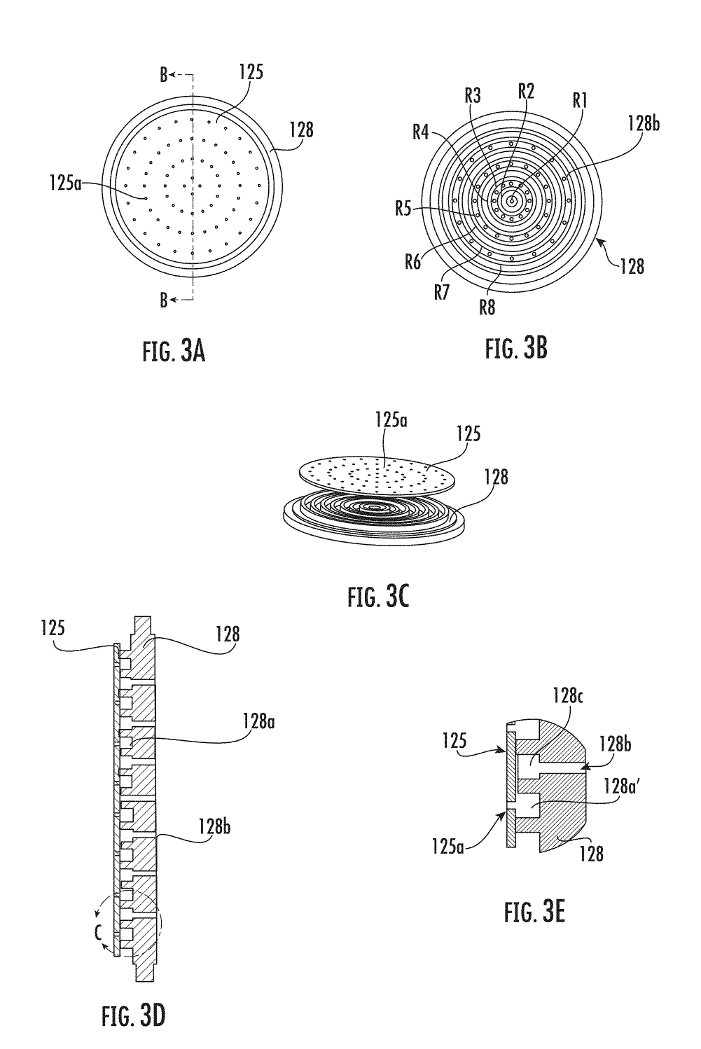

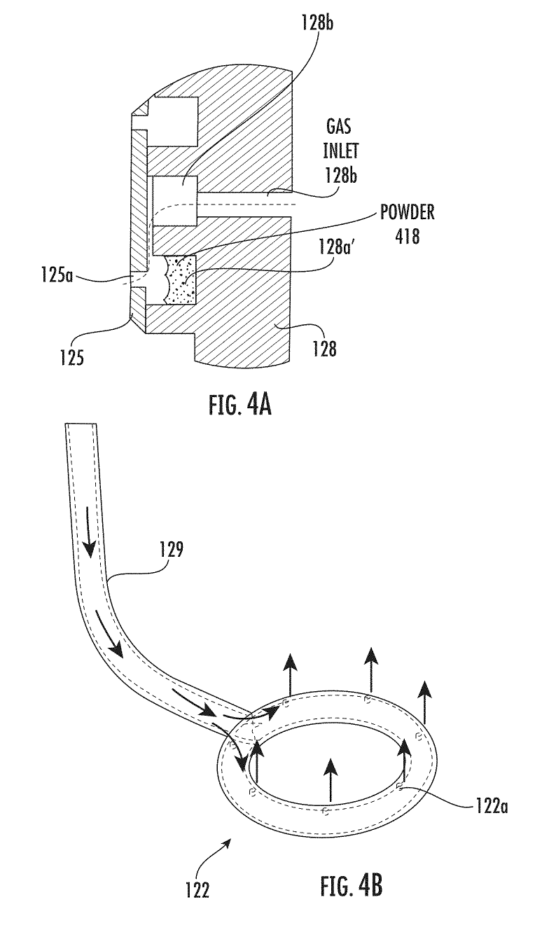

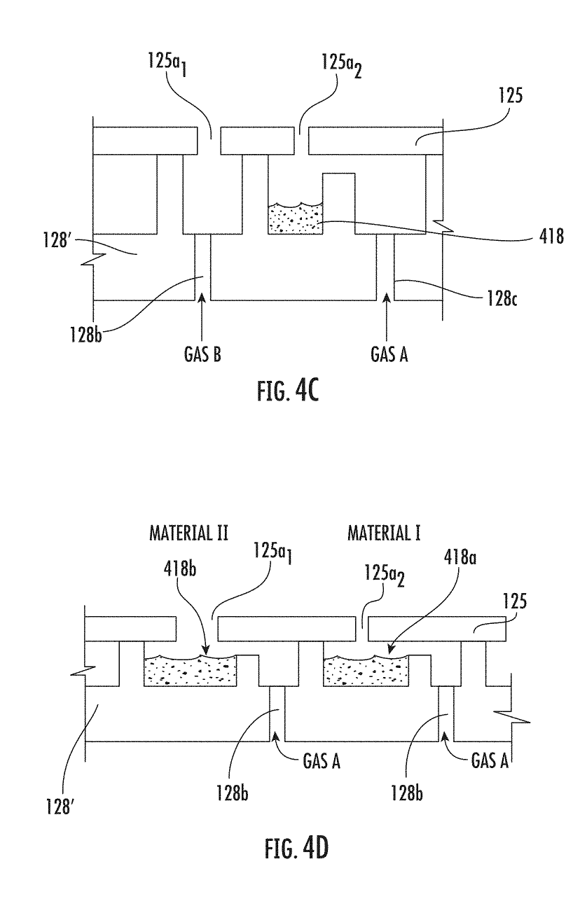

The vapor generating showerhead 125/128 comprises a precursor boat 128 having a plurality of gas inlets 128b fluidically coupled to precursor holder trenches 128a (both shown in FIG. 3E described below) for holding a vapor generating material and gas distribution plate 125 thereon having a plurality of flow distributing apertures 125a that is on top of the precursor boat 128. In the flow up arrangement used in the vertical deposition system 100, the gas distribution plate 125 being on top plate is generally only secured in place by gravity. In the reverse configuration for the vertical deposition system 150 shown in FIG. 1B, clamp arrangement is generally used to secure the gas distribution plate 125 to the precursor boat 128. The gas inlets have a flow path for flowing at least the first gas (e.g., an inert gas) over the vapor generating material for generating a reactant vapor that flows out of at least a portion of the flow distributing apertures 125a toward the substrate holder 130 (see FIG. 4A described below).

The precursor boat 128 is a plate generally comprising quartz having several alternating ringed trenches (or grooves, see FIG. 3B described below). An example precursor boat 128 is detailed in FIGS. 3A-E described below with several views from different angles. The gas distribution plate 125 functions as a cover and showerhead for the precursor boat 128. The gas distribution plate 125 can be a quartz plate that has flow distributing apertures 125a.

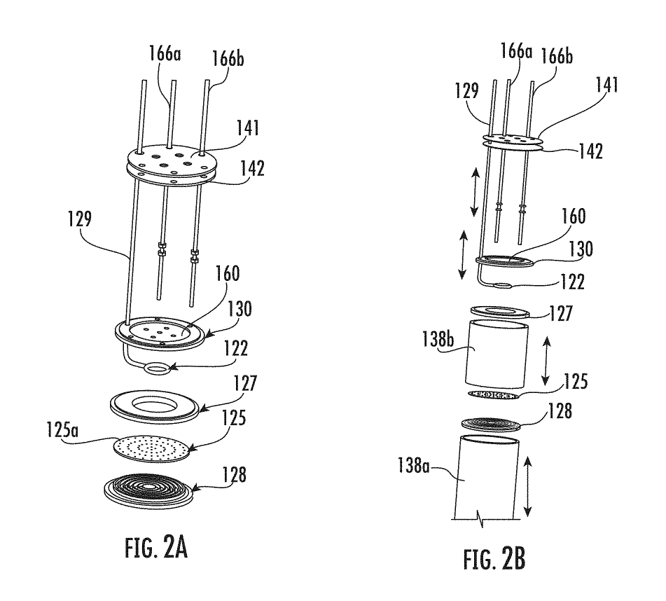

There is also a substrate holder 130 that can hold one or more substrates such as wafers. The substrate holder 130 may include features to enable rotation such as a bolt to the substrate holder 130 in the face down configuration, or it can be held by gravity in the reverse direction. In either case the shaft of the bolt can be a central solid rod or a hollow shaft cylinder. Such rotation can be used to further improve deposition uniformity across the wafer. There is a reactant gas distribution ring 122 having apertures 122a (see apertures 122a shown in FIG. 4B) coupled by a feed line 129 to the reactant gas inlet 121 which is proximate to the substrate holder 130. The reactant gas distribution ring 122 is positioned to feed reactant gas to mix with that of the reactant vapor from the vapor generating showerhead 125/128. The reactant gas distribution ring 122 is generally a quartz tube that can come from the top or bottom of the system with a ring tube on the end to deliver evenly distributed gas toward the substrate. The reactant gas distribution ring 122 can be slid up and down relative to the substrate holder 130 for example using threaded rod supports 166a, 166b shown in FIG. 2A.

The vapor generating showerhead 125/128 sits on a spacer tube 138a that comprises a hollow tube which sets the distance between the source material holder and the vapor generating showerhead 125/128 and the bottom flange 116. The precursor boat 128 is generally loaded with a vapor generating material from the bottom flange 116 and all other system components from the top flange 120. The spacer tube 138a can be replaced with a spacer tube having a different height to adjust the spacing between the source material holder and vapor generating showerhead 125/128 and the bottom flange 116. There is another spacer tube 138b between the vapor generating showerhead 125/128 and the baffle 127. The first gas connector 115 and the reactant gas connector 121 can be reversed in position.

There is also a flow baffle 127 between the source material holder and vapor generating showerhead 125/128 and the substrate holder 130. The flow baffle 127 provides flow shaping for the first gas and precursor flowing up from the bottom of the vertical process tube 110. This is generally a quartz plate with a smaller inner diameter that pushes the gas flow toward the center to evenly coat the substrate. The baffle 127 sits on a spacer tube 138b which can be replaced with a quartz tube of a different height to adjust the height of the baffle 127 relative to the substrate holder 130 and the precursor boat 128). The substrate holder 130 is supported by support rods 136. A furnace wall 108 is also shown in FIG. 1A.

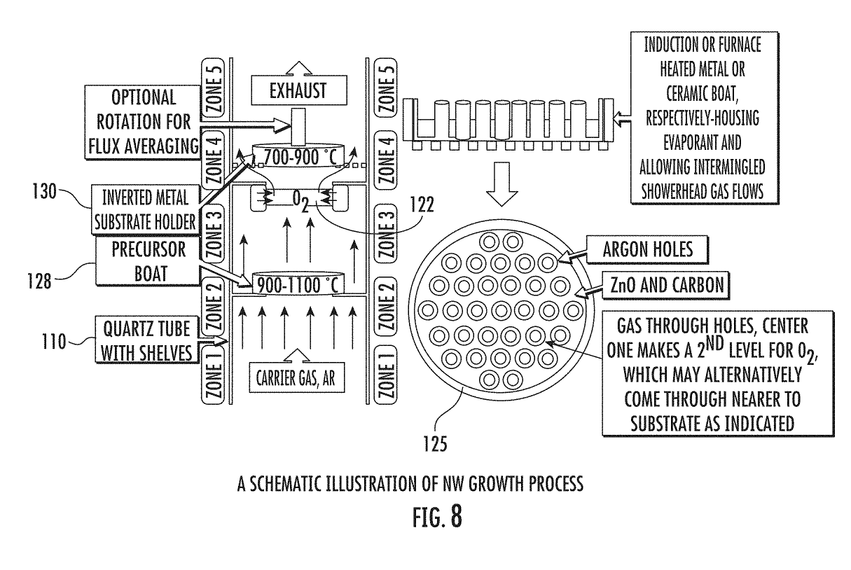

The deposition zone includes a plurality of zone heaters, such as five heaters as shown in the example NW or thin film deposition system in FIG. 8 described below. The number of heaters can be increased or decreased from 5. RF induction or lamp heating can be used for the heaters 135. A vacuum pump which is generally part of the vertical deposition system 100 is coupled to the vertical process tube 110 is not shown, which is included when operating the vertical deposition system 100 at reduced/vacuum pressures. The vertical deposition system 100 generally also includes a control system (not shown) for better repeatability, such as including a start/start switch, and controls to control the temperature and gas flows.

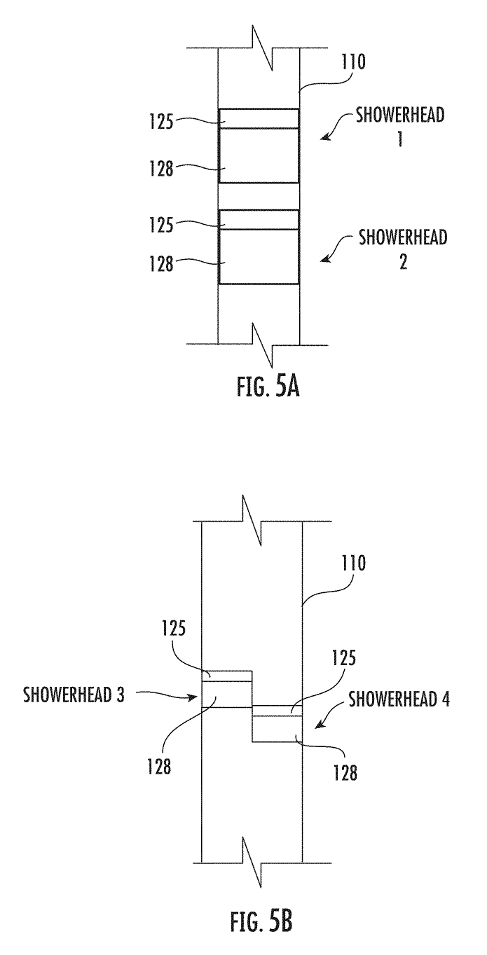

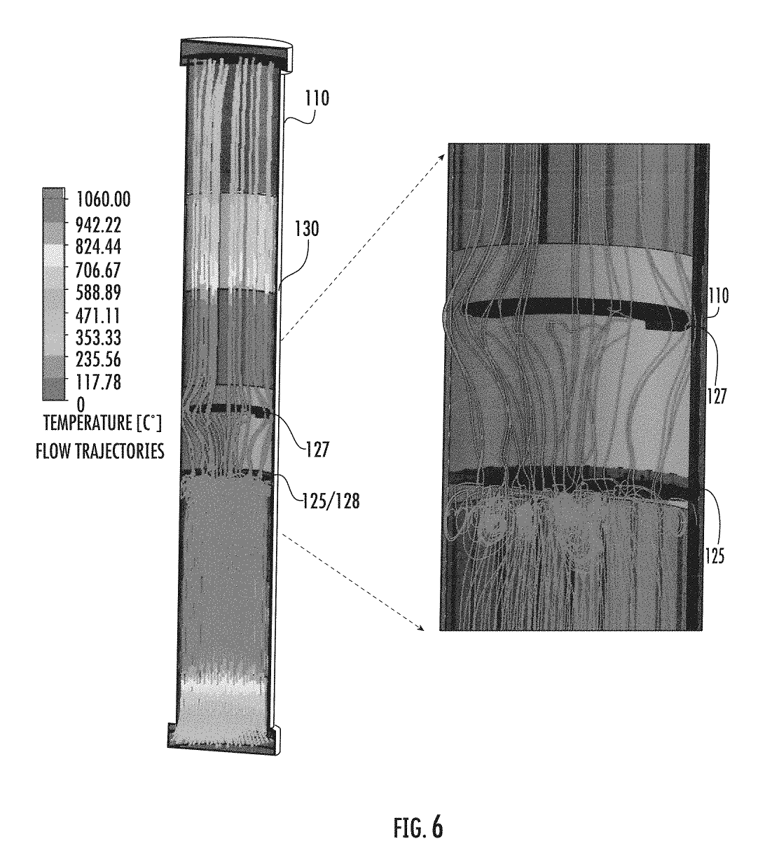

The vertical deposition system 100 is reconfigurable in several regards. Reconfiguration can be realized by the number and level of vapor sources and gases that can be placed in series (see FIG. 5A described below) or placed in parallel (see FIG. 5B described below). Further, as noted above the gas connectors can be switched between the top and bottom. The multiple heating zones provide flexibility in maintaining temperature gradient, several exchangeable spacing tubes 138 enable varying the internal separation and flow diverting rings may be utilized as needed for improved gas flow management.

FIG. 1B is a cross sectional depiction of an example downward facing vertical deposition system 150 and having internal tube components flipped 180 degrees in position relative to the vertical deposition system 100 shown in FIG. 1A. The system geometry in vertical deposition system 150 being inverted can alter the effects of gravity and thermal induced flow. Swift rotation of the substrate holder 130 (e.g., 500 to 1500 rotations per minute (rpm)) as described above can be used to generate forced convection to induce laminar downward flow and hence increase efficiency and uniformity. An alternative vapor generating showerhead may be used for a downward facing vertical deposition system such that the source material holder and vapor showerhead's temperature control can be in the showerhead region of the heating furnace and such that solids, powders or melted material can be held without dropping down. Essentially the same showerhead 125/128 may be used, for reversing the flow.

FIG. 2A shows in more detail the components within the vertical process tube with the vapor generating showerhead 125/128 shown in an exploded view to more clearly show the gas distribution plate 125 and the precursor boat 128. Heat shields 141 and 142 are also shown above the substrate holder 130 that holds a substrate (e.g., a wafer) 160 which can be moved up and down on the threaded rod supports 166a, 166b. FIG. 2B modifies FIG. 2A by adding spacer tubes 138b, 138a above and below the gas distribution plate 125 on the precursor boat 128 so that the distance (shown as a 2-sided arrow) from the gas distribution plate 125 on the precursor boat 128 can be changed relative to the substrate holder 130.

FIG. 3A shows a top view of a gas distribution plate 125 on a precursor boat 128. FIG. 3B shows the precursor boat 128 having a plurality of trenches shown as rings R1 to R8, where some of the rings are precursor holder trenches 128a. From the center of the precursor boat 128, rings R1, R3, R5, and R7 are trenches 128c that have gas inlets 128b for distributing the first gas received from below in FIG. 1A. Rings R2, R4, R6, and R8 are precursor holder trenches 128a for holding vapor generating material such as sublimating powder or a liquid precursor. The first gas from ring R1 flows over the powder or liquid vapor generating material in ring R2, the first gas from R3 over the vapor generating material powder or liquid in R4, etc. (see FIG. 4A described below).

FIG. 3C shows an exploded view of a gas distribution plate 125 and a precursor boat 128 that makes clear the ring shaped trenches and the walls surrounding the trenches. FIG. 3D shows a cross sectional view along the cut line B-B shown in FIG. 3A of a gas distribution plate 125 on a precursor boat 128. Gas inlets are shown 128b, and to precursor holder trenches 128a are again shown ring shaped. FIG. 3E shows an expanded view of the circled portion of the vapor generating showerhead 125/128 in FIG. 3D, where a precursor holder trench portion 128a′ is shown that is where the vapor generating material is stored.

FIG. 4A depicts a first gas such as inert gas flowing through gas inlet flowing over powder shown within one of the rings shown as, then out an aperture in the gas distribution plate such as gas from ring R1 flows over the powder in ring R2, from ring R3 over R4, and so on. As shown in FIG. 4A, the gas inlet 128b associated with trench 128c can be seen guided laterally by the gas distribution plate 125 to allow gas to flow to an adjacent trench portion shown as 128a′ that has vapor generating material therein to generate reactant vapor which flows out of flow distributing apertures 125a. As described above, the flow distributing apertures 125a are positioned above rings R2, R4, R6 and R8 that are precursor holder trenches 128a for holding vapor generating material so the first gas flow from below is forced to pass above the vapor generating material before going out of the precursor boat 128. FIG. 4A depicts a first gas, such as inert gas, flowing through gas inlet 128b being directed by the gas distribution plate 125 to flow over powder 418 that is within one of the trenches shown as 128a′, then out a flow distributing aperture 125a in the gas distribution plate 125.

FIG. 4B shows gas flowing out of the apertures 122a of the reactant gas distribution ring 122. A feed line 129 is shown in FIG. 4B that is coupled between the reactant gas connector 121 and the reactant gas distribution ring 122.

FIG. 4C shows an alternate operation mode for the precursor boat, 128′, where in addition to an inert or reactive gas flowing through an aperture 128b and then over the powder 418 and toward the substrate through a flow distributing aperture now shown as 125a1 in the precursor boat plater 125, a second or identical gas is also flowed through a separate trench 128c in the precursor boat and through a separate flow distributing aperture 125a2 in the precursor boat plate 125. FIG. 4D shows an alternate operational mode for the precursor boat, 128″, where in addition to an inert or reactive gas flowing through an aperture 128b over the first powder Material I 418a and out through a flow distributing aperture 125a2, an inert or reactive gas flows over a second powder Material II 418b through a separate set of apertures 128a in a separate ring in the precursor boat 128″ and then out through an flow distributing aperture 125a1.

Disclosed vertical deposition systems have been verified by experiment and by thermal and flow modeling to present a large area growth surface at a uniform growth temperature to a uniform flux of precursor materials. The disclosed vertical deposition system 100 has multiple source stages and uniformly deposits NWs and thin films on different size wafers up to 100 mm for the specific prototype system model created. However, a disclosed system can be designed to uniformly deposits NWs and thin films on wafers sizes >100 mm by scaling to a larger vertical process tube 110 with a larger precursor boat 128 with more rings. Disclosed vertical deposition system also provides control of a wide range of process parameters including the temperature, pressure, and variable distance of the source materials, wafer, and oxidizer for the oxide NW or film growth.

Contrary to conventional NW or thin film growth and hydride vapor phase epitaxy (HVPE) systems, for disclosed vertical deposition systems, NWs or thin films are grown on inverted substrates (i.e. ones where the deposition plane is facing downward) in a vertical tube. The vertical deposition system has been designed to avoid the depletion (as different precursor materials generally decay at differing rates) problems resulting in composition, structure, and general uniformity variation problems. It is noted that while the prototype vertical deposition system that was built and demonstrated was for ZnO-based NW growth, the system can equally well work with other equivalent material systems, or others that benefit from the same geometrical process benefits being the flows and options of an evaporated source, seed or catalyst materials. For example, deposition systems for application to carbon nanotubes, SiGe nanowires, and MgB₂. Chlorine or HCl passed over precursor materials that form chlorides will, with a disclosed showerhead, be a source of chlorides for HVPE or similar thin film growth. It is also noted that disclosed vertical deposition systems can also work with reactive gases coming from the bottom and passing over a solid, that reacts' with the solid to form a vapor, which can be used to transport precursor to the deposition plane for film on NW growth thereafter growing films or NWs.

FIG. 5A shows a series vapor generating showerhead connection shown as showerhead 1 and showerhead 2. The use of two precursor boat sources in series allows them to be operated at different temperatures appropriate to their generating a vapor for transport to the substrate and passing the more stable vapor through the next vapor generation zone.

FIG. 5B shows a parallel vapor generating showerhead connection shown as showerhead 3 and showerhead 4. Two side by side sources, or height different “side by side” sources, provides the opportunity to use sources at near the same temperature that might otherwise react together in a way that prohibits process desirable vapor transport and thus would otherwise not produce film or nanowire coatings. Further, by rotating the substrate the flows can be “homogenized” at the surface so as to a compositionally uniform film or nanowire at the growth interface.

### Examples

Disclosed embodiments are further illustrated by the following specific Examples, which should not be construed as limiting the scope or content of this Disclosure in any way.

Uniform temperature and gas flow profiles along the full wafer area is recognized to be important to achieve uniform NW or thin film growth. Temperature and gas flow modeling (simulation) of the vertical deposition system 100 shown in FIG. 1A was performed with SOLIDWORKS™ flow simulation to be able to perform uniform Zn(Mg)O NW growth on Si wafers whose sizes ranged from 1 cm² to 100 mm² in diameter. FIG. 6 shows results from temperature modeling showing a uniform thermal distribution along the process tube 110 around the precursor boat 128 and the substrate holder 130. In this model, all heaters around the process tube 110 were kept at 1050° C., except that the heater located on top was kept at 650° C. The chamber pressure was chosen to be 5 Torr for the modeling.

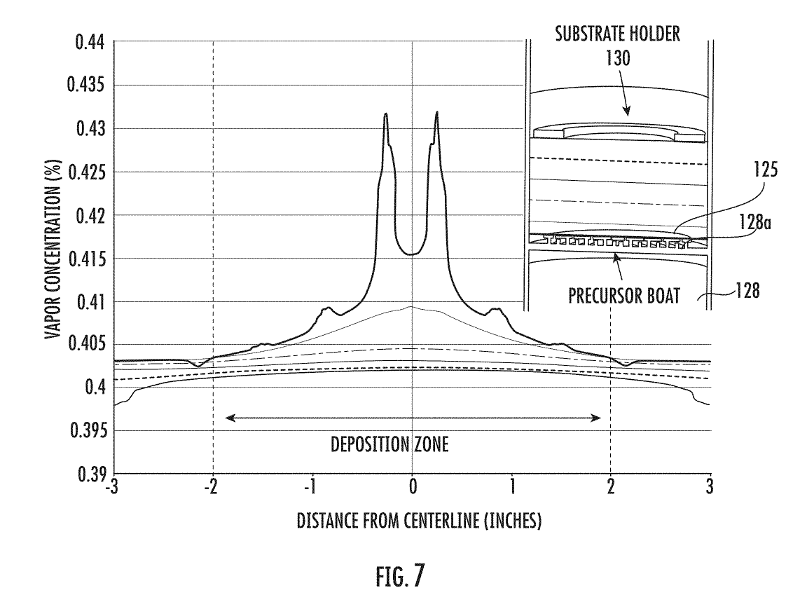

The precursor carrying gas, argon in this case, and reactive gas, O₂ in this case, were introduced into the reactor with flow rates of 100 and 500 cc, respectively. The distance between the precursor boat 128 having ZnO powder in the precursor holder trenches 128a and the substrate holder 130 was 50 cm. FIG. 7 shows the ZnO vapor concentration in % (as it is mixed with argon and O₂) along the distance (in inches) between the precursor boat 128 and the substrate holder 130. As can be seen from FIG. 7, the distance between the precursor boat 128 and the substrate holder 130 is important for a uniform NW of thin film growth. The ZnO vapor distribution is relatively non-uniform at the precursor boat 128. At this point, the initial or central trenches cause about 7-8% peaking in vapor concentration. The vapor concentration changes along the distance and becomes uniform near and on the substrate holder's 130 surface. A uniform Zn(Mg)O growth on a wafer 100 mm in diameter placed on the substrate holder 130 was also confirmed by experiments performed.

Disclosed vapor generating showerheads 125/128 may be mounted face up or down or at other angles. They may be used in deposition systems where the injection point is close to the temperature controlled substrate (close space) or far from the substrate, but in each case where the thermal budgets of single or groups of reactant materials have thermal range limits that are otherwise in conflict with their co-usage. The shown multilevel showerhead with active heated and cooled zones, thermal barriers and gas knives mitigates or prevents vapor transport pre-reactions. This showerhead is particularly attractive for close space injection of vapors that are relatively temperature sensitive to decomposition injected adjacent with vapors that must be kept at temperatures higher than that at which the temperature sensitive vapors would decompose, into a reactor (with minimal thermal pre-reaction) where the chemicals react at or about a temperature controlled surface to form a film or nanowires. The chemical reactor may perform VS, VLS, CVD, ALD, HVPE, MBE, and so on or combinations of such techniques. The temperature controlled substrate may be oriented in process conducive orientations, typically face up or face down. Materials that can be grown with this type of apparatus include: oxides such as ZnMgO, Ga₂O₃, and InAlGaO among others; nitrides such InGaN; borides such as MgB₂; III-V or II-VI semiconductors; and so on.

Flow model simulations of the showerhead were conducted using SOLIDWORKS. Gas flows and temperatures were kept constant for each of the three injectors, and then the models were varied on chamber pressure from 0.76 Torr to 760 Torr to examine the effect of pressure on the flow parameters. A uniform flow is observed for the lower pressure levels (0.76 and 7.6 Torr) with flow from the top injectors splitting to both sides of the sublimation source channels. The most of the flow reaching the substrate appears to come from the central three injectors, suggesting that the outer two injectors will primarily be used to tune the uniformity. At pressures of 76 and 760 Torr, recirculation cells led to more uneven flow conditions.

While various disclosed embodiments have been described above, it should be understood that they have been presented by way of example only, and not limitation. Numerous changes to the subject matter disclosed herein can be made in accordance with this Disclosure without departing from the spirit or scope of this Disclosure. In addition, while a particular feature may have been disclosed with respect to only one of several implementations, such feature may be combined with one or more other features of the other implementations as may be desired and advantageous for any given or particular application.

1. A deposition system, comprising:
a process tube aligned vertically having a vertical tube axis with a substrate holder therein for holding at least one substrate positioned horizontally and perpendicular to the vertical tube axis;
a bottom flange on a bottom of the process tube, a top flange on a top of the process tube, and an exhaust port on the top flange or on the bottom flange;
through at least one of a bottom flange and the top flange a first gas line connector for injecting at least a first gas and at least one reactant gas connector for injecting at least one reactant gas, and a feed line coupled between the reactant gas connector and a reactant gas distributor having apertures for flowing the reactant gas towards the substrate, and
a vapor generating showerhead comprising a gas distribution plate having a plurality of flow distributing apertures on top of a precursor boat having a plurality of gas inlets fluidically coupled to precursor holder trenches for holding a vapor generating material, the gas inlets having a flow path for flowing at least the first gas over the vapor generating material that is inert or slow reacting relative to the reactant vapor for generating a reactant vapor that flows out of at least a portion of the flow distributing apertures toward the substrate.

2. The system in claim 1, wherein the precursor boat is supported by a first spacer tube that is removably coupled to be replaced with another spacer tube that has a different height to adjust a height of the precursor boat relative to the bottom flange.

3. The system in claim 1, wherein the precursor holder trenches comprises a plurality of ringed grooves including a first set of rings that are each fluidically coupled by a flow path including one of the gas inlets to one of a second set of rings that have the vapor generating material and have the flow distributing aperture thereover.

4. The system in claim 3, wherein the plurality of flow distributing apertures include a first set of apertures for flowing the first gas received towards the substrate and a second set of apertures above the second set of rings for flowing the reactant vapor that is a mixed gas with the reactant vapor being mixed with the first gas toward the substrate.

5. The system in claim 1, further comprising a flow baffle between the gas distribution plate and the substrate holder having a center aperture that is supported by second spacer tube that is removably secured to be replaced with another spacer tube that has a different height to adjust a height of the precursor boat relative to the bottom flange.

6. The system in claim 1, wherein the gas reactant gas distributor comprises a reactant gas distribution ring that is configured to be slid up and down relative to the substrate holder.

7. The system in claim 1, wherein the gas line connector for injecting the first gas and the reactant gas connector for injecting the reactant gas are through different ones of the bottom flange and the top flange.

8. The system in claim 1, wherein the vapor generating showerhead includes a series connected first and second vapor generating showerhead.

9. The system in claim 1, wherein the vapor generating showerhead includes a parallel connected first and second vapor generating showerhead.

10. A method for depositing a thin film, comprising:
providing a deposition system comprising a heated vertically aligned process tube having a vertical tube axis with a substrate holder therein for holding at least one substrate positioned horizontally and perpendicular to the vertical tube axis;
injecting at least a first gas and at least one reactant gas into the process tube towards the substrate, and
generating a reactant vapor using a vapor generating showerhead comprising a gas distribution plate having a plurality of flow distributing apertures on top of a precursor boat having a plurality of gas inlets fluidically coupled to precursor holder trenches for holding a vapor generating material, the gas inlets having a flow path for flowing at least the first gas over the vapor generating material that is inert or slow reacting relative to the reactant vapor for generating a reactant vapor that flows out of at least a portion of the flow distributing apertures toward the substrate.

11. The method of claim 10, wherein the vapor generating material comprises a sublimation powder and the reactant gas comprises oxygen.

12. The method of claim 10, wherein the thin film comprises nanowires.

13. The method of claim 10, wherein the precursor boat is supported by a first spacer tube that is removably coupled, further comprising replacing the first spacer tube with another spacer tube that has a different height to adjust a height of the precursor boat relative to a flange.

14. The method of claim 10, wherein the precursor boat comprises a plurality of ringed grooves with a first set of rings having apertures for distributing at least the first gas received from below to the gas distribution plate alternating with a second set of rings having apertures for distributing the reactant vapor to the gas distribution plate.

15. The method of claim 10, wherein the plurality of flow distributing apertures include a first set of apertures for flowing the first gas received towards the substrate and a second set of apertures above the second set of rings for directing another gas over the vapor generating material before flowing the reactant vapor toward the substrate.

16. The method of claim 10, wherein the deposition system further comprises a flow baffle between the gas distribution plate and the substrate holder having a center aperture that is supported by second spacer tube that is removable secured, further replacing the second spacer tube with another spacer tube that has a different height to adjust a height of the precursor boat relative to the bottom flange.

17. The method of claim 10, wherein the reactant gas distributor comprises a reactive gas inlet ring that is configured to be slid up and down relative to the substrate holder, further comprising sliding the reactive gas inlet ring up or down relative to the substrate holder.

18. The method of claim 10, wherein rotating the substrate holder to rotate the substrate.

19. A vapor generating showerhead, comprising:
a gas distribution plate having a plurality of flow distributing apertures on top of a precursor boat having a plurality of gas inlets fluidically coupled to precursor holder trenches for holding a vapor generating material,
wherein the gas inlets have a flow path for flowing at least a first gas over the vapor generating material for generating a reactant vapor that flows out of at least a portion of the flow distributing apertures.

20. The vapor generating showerhead of claim 19, wherein the precursor holder trenches comprises a plurality of ringed grooves including a first set of rings that are each fluidically coupled by a flow path including one of the gas inlets to one of a second set of rings that have the vapor generating material therein and have a portion of the flow distributing aperture thereover.

21. The vapor generating showerhead of claim 20, wherein the plurality of flow distributing apertures include a first set of apertures for flowing the first gas received towards the substrate and a second set of apertures above the second set of rings for directing another gas flow over the vapor generating material before flowing the reactant vapor toward the substrate.

22. The vapor generating showerhead of claim 19, wherein the precursor holder trenches comprises a plurality of ringed grooves including a first set of rings that are each fluidically coupled by a flow path including one of the gas inlets to one of a second set of rings that have a first one of the vapor generating material therein and have a portion of the flow distributing aperture thereover, and a third set of rings that are each fluidically coupled by a flow path including one of the gas inlets to one of a fourth set of rings that have a second one of the vapor generating material therein and have a portion of the flow distributing aperture thereover.
